(19) United States
(12) Patent Application Publication
(10) Pub. No.: US 2011/0241059 A1
(43) Pub. Date: Oct. 6, 2011

(54) LED DIE STRUCTURE AND METHOD FOR MANUFACTURING THE BOTTOM TERMINAL THEREOF

(75) Inventor: HUI-HENG WANG, TAOYUAN COUNTY (TW)

(73) Assignee: ARIMA OPTOELECTRONICS CORP., TAOYUAN COUNTY (TW)

(21) Appl. No.: 12/749,816

(22) Filed: Mar. 30, 2010

(51) Int. Cl. H01L 33/00; H01L 21/78

(52) U.S. Cl. 257/99; 438/33; 257/E21.599; 257/E33.066; 257/E33.055

(57) ABSTRACT

An LED die structure and a method for manufacturing the bottom terminal of the LED die structure, wherein the LED die includes a substrate, a light-emitting layer positioned at the top of the substrate, at least one bottom terminal positioned at the bottom of the substrate, at least one top terminal positioned at the top of the light-emitting layer, and at least one side terminal positioned at the side of the bottom of the substrate, and wherein the method comprises the following steps: a) recessing the bottom side of the wafer to a predetermined height when the LED is formed in a wafer type; b) coating the metal material to the bottom of the wafer and to the inside of the recesses; and c) dividing the wafer along the recesses into dies. In this way, the bottom terminal and the side terminal are formed at the bottom of the substrate of the die. Moreover, the LED die structure enhances the quality of the electric connection between the die-bonding paste and the LED die.

### BACKGROUND OF THE INVENTION

1. Field of the Invention

The invention relates to an LED die structure and a method for manufacturing the bottom terminal thereof, and more particularly to a bottom terminal consisting of a bottom and side terminal that ensures a stable quality of the electric connection when applied to a vertically conducted type LED packaging/assembly arrangement.

2. Description of the Related Art

Light-emitting diodes (LED) have a small size and a high luminous efficiency. Moreover, they are able to emit a light having different colors, thereby ensuring a various application. As a result, a lot of packaging (assembly) shapes has been created. The packaged products are generally known as lamps or SMD (surface mounting device). Apart from the appearance, another important consideration point is the quality reliability. Therefore, the die bonding is an important step for both the lamp arrangement and the SMD-arrangement before or after the packaging process. The term “die bonding” refers to a process in which an LED die is sucked, adhered or clamped first, and then placed on a solid lead frame coated with sticky and liquid plastic material. Meanwhile, a certain pressure is applied to ensure a firm attachment of the bottom of the LED die to the liquid plastic material. Thereafter, a heating process is carried out to solidify the plastic material, thereby completing the die bonding process.

The lead frame is made of metal material or coated with a solid material (such as metal film). The selection of the metal material lies in that the metal material features an easy processing and an excellent heat-dissipation. Particularly, the electric conductivity is necessary for some LED dies. For example, the electric current of the vertical LED flows in from the upper terminal pad and passes vertically through the die. Finally, it flows out from the bottom. The package has to employ the lead frame having the electric conductivity. The silver paste is a widely used die-bonding paste. Apart from the viscosity and the fluidity, the silver paste also has the electric conductivity due to the incorporation of silver powder. As a result, the combination of the vertical die, the die-bonding paste and the conductive lead frame creates a top-bottom current path. Such structural design is commonly found in LED components made of quaternary materials, and has become heavily commercialized.

As shown in FIG. 1, a typical (vertically conducted type) LED packaging/assembly arrangement has a vertical LED die 10. The bottom thereof is adhered to a first lead frame 30a by the conductive die-bonding paste 20, thereby establishing an electric connection of the bottom terminal pad 11 to the first lead frame 30a. The top terminal pad 12 is electrically connected via a lead 31 to a second lead frame 30b. In this way, the electric current may flow in from the first lead frame 30a. After passing through the LED die 10, the electric current exits from the second lead frame 30b. Therefore, the die-bonding process for the vertical type LED die 10 has to meet strict requirements to ensure a stable electric conductivity. The die-bonding quality will be affected if the following conditions occur:
1. The back of the die is not flat and/or smooth;
2. The surface of the lead frame is not flat and/or smooth;
3. The viscosity of the silver paste is bad and a limited use period thereof is expired;
4. The storage and thawing conditions do not meet the requirements;
5. If the recess for the silver paste is regularly cleaned; and
6. If the other factors such as environment dust, temperature, humidity, etc. is abnormal.

However, it is apparent from the cross-sectional view of the die-bonding structure in FIG. 2 that bad connections such as gaps take place at the joint between the bottom of the LED die 10 and the die-bonding paste 20 while the connection between the side of the LED die 10 and the die-bonding paste 20 is maintained in a good state. The above-mentioned conditions tend to cause the electric instability of the LED assembly elements. The air inside the gap expands and contracts especially when a heat/cold cycle is carries out, making the quality of the electrical connection between the die-bonding paste 20 and the LED die 10 even worse.

### SUMMARY OF THE INVENTION

An object of the invention is to provide an LED die structure and a method for manufacturing the bottom terminal thereof that enhances the quality of the electric connection between the die-bonding paste and the LED die.

In order to achieve the above-mentioned object, the invention includes:

a) a substrate;

b) a light-emitting layer positioned at the top of the substrate;

c) at least one bottom terminal positioned at the bottom of the substrate;

d) at least one top terminal positioned at the top of the light-emitting layer; and

e) at least one side terminal positioned at the side of the bottom of the substrate.

According to the invention, the height of the side terminal is adapted to the height of the die-bonding paste for the packaging process. The die-bonding paste comprises silver paste. The material for the substrate is selected from a group, consisting of Si, Ge, GaAs, and GaP.

According to the invention, a method for manufacturing the bottom terminal of the LED die structure, wherein the method comprises the following steps:

a) recessing the bottom side of the wafer to a predetermined height when the LED is formed in a wafer type;

b) coating the metal material to the bottom of the wafer and to the inside of the recesses (by use of the metal coating process); and

c) dividing the wafer along the recesses into dies,

whereby the bottom terminal and the side terminal are formed at the bottom of the substrate of the die.

According to the invention, another method for manufacturing the bottom terminal of the LED die structure, wherein the method comprises the following steps:

a) dividing the LED wafer into dies; and

b) coating the metal material to the bottom and the sides of the dies (by use of the metal coating process),

whereby the bottom terminal and the side terminal are formed at the bottom of the substrate of the die.

### BRIEF DESCRIPTION OF THE DRAWINGS

The accomplishment of this and other objects of the invention will become apparent from the following descriptions and its accompanying figures of which:

FIG. 1 is a cross-sectional view of a typical (vertically conducted type) LED packaging/assembly arrangement;

FIG. 2 is an image of the die-bonding structure of the LED in longitudinal section;

FIG. 3 is a schematic drawing of the die structure of the invention;

FIG. 4 is a cross-sectional view of a packaging structure employing the die structure of the invention;

FIG. 5 is a flow chart of a method for manufacturing the bottom terminal thereof; and

FIG. 6 is a flow chart of another method for manufacturing the bottom terminal thereof.

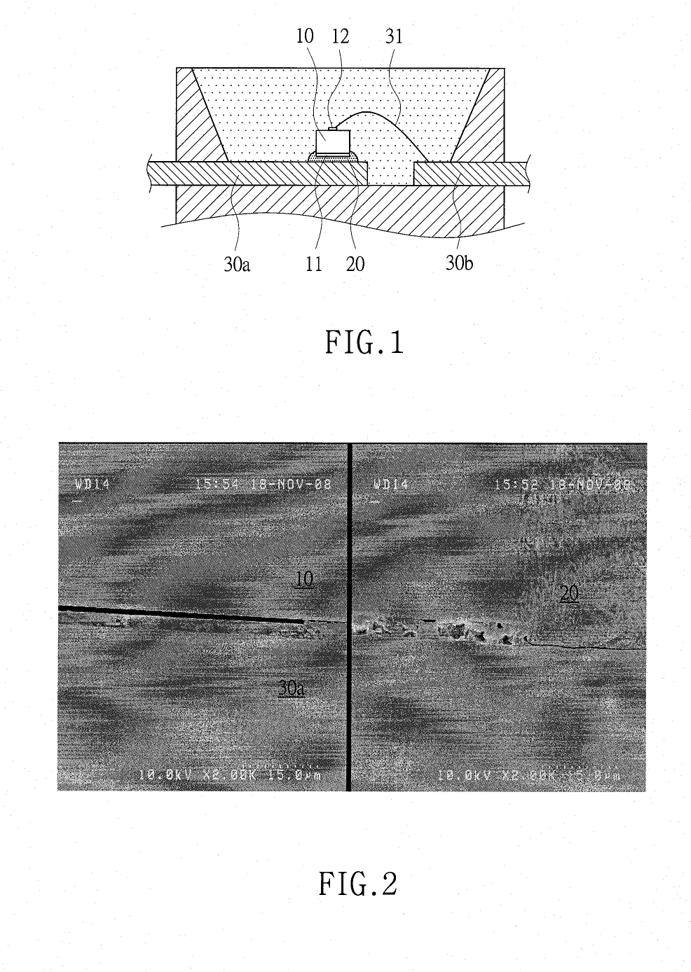

### DETAILED DESCRIPTION OF THE PREFERRED EMBODIMENT

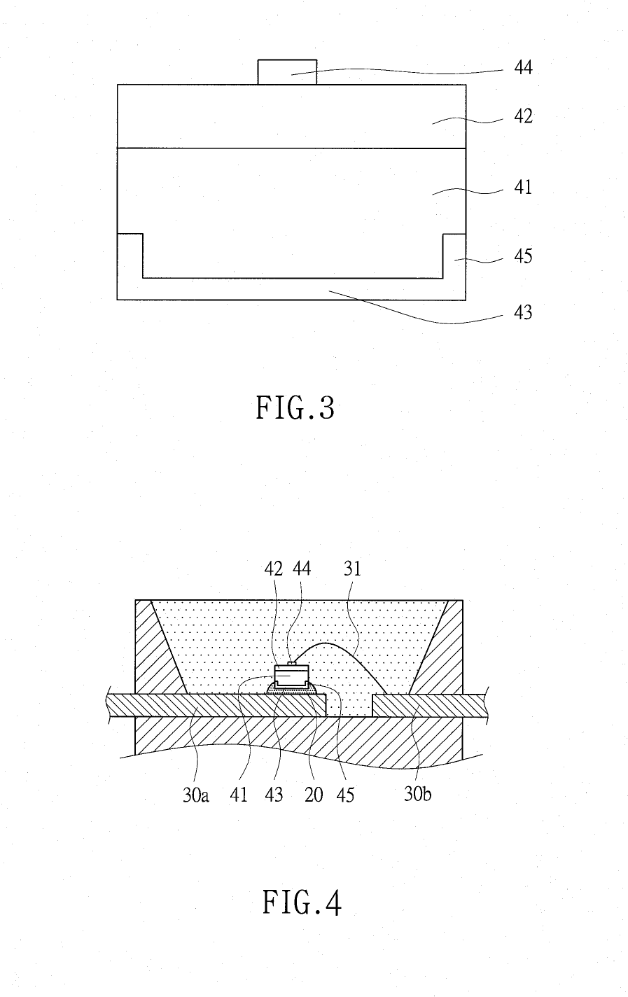

First of all, referring to FIGS. 3 and 4, the LED die structure in accordance with the invention includes a substrate 41, a light-emitting layer 42 positioned at the top of the substrate 1, at least one bottom terminal 43 positioned at the bottom of the substrate 41, at least one top terminal 44 positioned at the top of the light-emitting layer 42, and at least one side terminal 45 positioned at the side of the bottom of the substrate 41.

According to the invention, the LED die structure improves the design of the terminal. In addition to the bottom terminal 43 and the top terminal 44, a side terminal 45 with a predetermined height is provided at the bottom of the substrate 41. After the packaging process, the lead 31 electrically connects the top terminal 44 and the second lead frame 30b, while the bottom terminal 43, the side terminal 45, and the second lead frame 30b are electrically connected by the die-bonding paste 20. When a bad contact takes place between the bottom terminal 43 of the die and the die-bonding paste 20, an instable electric connection may be avoided by the good connection of the side terminal 45 with the side wall of the die-bonding paste 20.

The material suitable for the substrate 41 may be Si, Ge, GaAs, or GaP. The bottom terminal 43 and the side terminal 45 may be formed by the metal coating process. The height of the side terminal 45 is adapted to the height of the die-bonding paste 20 for the packaging process. Moreover, the die-bonding paste 20 is the silver paste.

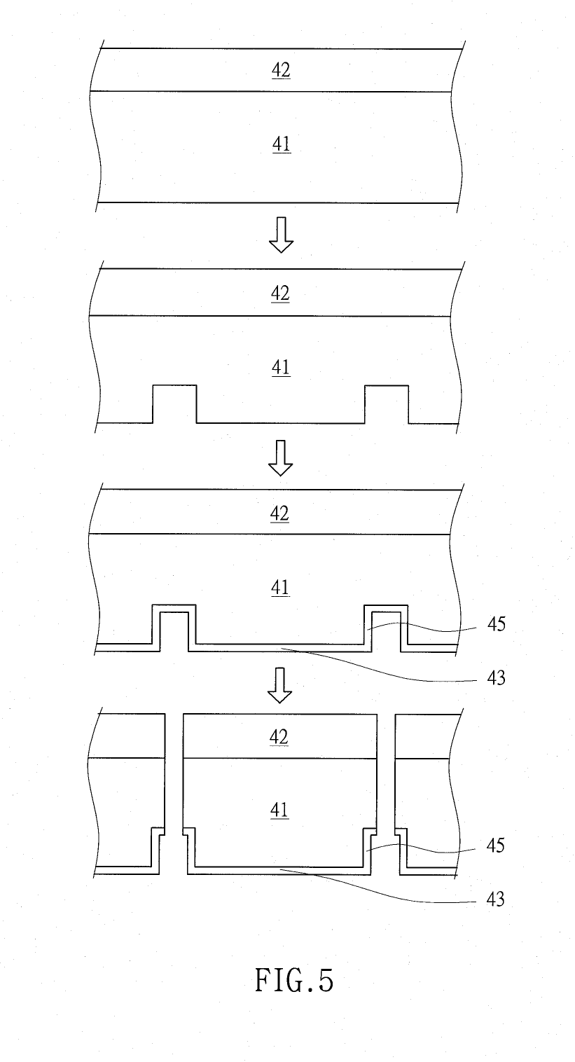

As shown in FIG. 5, a method for manufacturing the bottom terminal of the LED die structure of the invention includes the following steps:

Recessing the bottom side of the wafer to a predetermined height when the LED is formed in a wafer type;

Coating the metal material to the bottom of the wafer and the sides of the recesses (by use of the metal coating process having the coverage effect); and

Dividing the wafer along the recesses into dies by use of the cutting or breakup process.

In this way, the bottom terminal 43 and the side terminal 45 are positioned at the bottom of the substrate of the die.

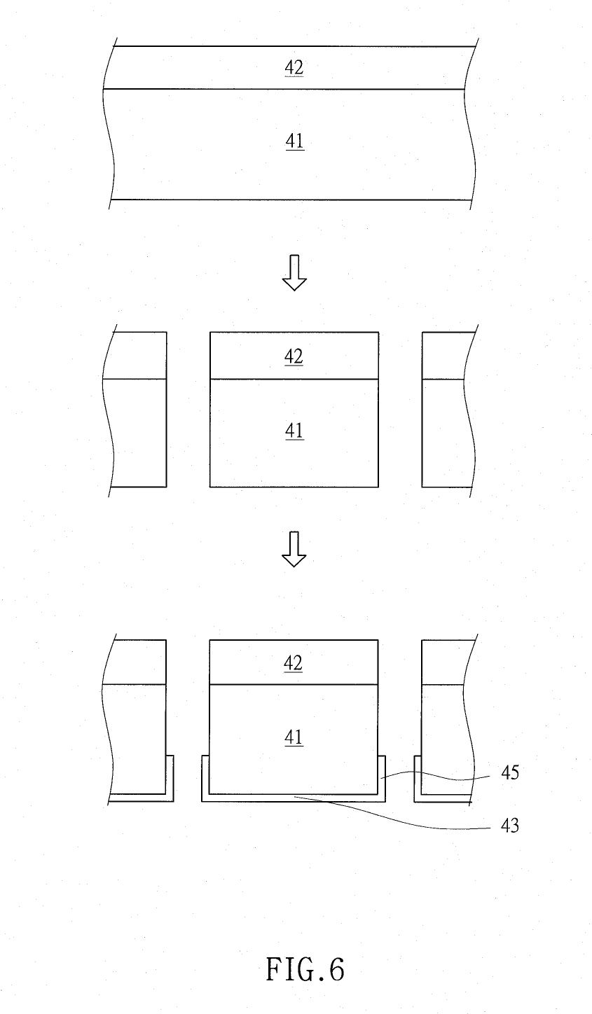

As shown in FIG. 6, another method for manufacturing the bottom terminal of the LED die structure of the invention includes the following steps:

Dividing the LED (in shape of wafer) into dies by use of the cutting or breakup process;

Coating the metal material to the bottom and the sides of the dies (by use of the metal coating process having the coverage effect); and

In this way, the bottom terminal 43 and the side terminal 45 are positioned at the bottom of the substrate of the die.

Many changes and modifications in the above-described embodiments of the invention can, of course, be carried out without departing from the scope thereof. Accordingly, to promote the progress in science and the useful arts, the invention is disclosed and is intended to be limited only by the scope of the appended claims.

What is claimed is:

1. An LED die structure, comprising:
a) a substrate;
b) a light-emitting layer positioned at the top of the substrate;
c) at least one bottom terminal positioned at the bottom of the substrate;
d) at least one top terminal positioned at the top of the light-emitting layer; and
e) at least one side terminal positioned at the side of the bottom of the substrate.

2. The LED die structure as recited in claim 1 wherein the height of the side terminal is adapted to the height of the die-bonding paste for the packaging process.

3. The LED die structure as recited in claim 2 wherein the die-bonding paste comprises silver paste.

4. The LED die structure as recited in claim 3 wherein the material for the substrate is selected from a group, consisting of Si, Ge, GaAs, and GaP.

5. A method for manufacturing the bottom terminal of the LED die structure, wherein the LED die includes a substrate, a light-emitting layer positioned at the top of the substrate, at least one bottom terminal positioned at the bottom of the substrate, at least one top terminal positioned at the top of the light-emitting layer, and at least one side terminal positioned at the side of the bottom of the substrate, and wherein the method comprises the following steps:
a) recessing the bottom side of the wafer to a predetermined height when the LED is formed in a wafer type;
b) coating the metal material to the bottom of the wafer and to the inside of the recesses (by use of the metal coating process); and
c) dividing the wafer along the recesses into dies,
whereby the bottom terminal and the side terminal are formed at the bottom of the substrate of the die.

6. The method for manufacturing the bottom terminal of the LED die structure as recited in claim 5 wherein the metal coating process achieves the coverage effect.

7. The method for manufacturing the bottom terminal of the LED die structure as recited in claim 6 wherein the wafer is divided into dies by use of the cutting or breakup process.

8. A method for manufacturing the bottom terminal of the LED die structure, wherein the LED die includes a substrate, a light-emitting layer positioned at the top of the substrate, at least one bottom terminal positioned at the bottom of the substrate, at least one top terminal positioned at the top of the light-emitting layer, and at least one side terminal positioned at the side of the bottom of the substrate, and wherein the method comprises the following steps:
a) dividing the LED wafer into dies; and
b) coating the metal material to the bottom and the sides of the dies (by use of the metal coating process),
whereby the bottom terminal and the side terminal are formed at the bottom of the substrate of the die.

9. The method for manufacturing the bottom terminal of the LED die structure as recited in claim 8 wherein the metal coating process achieves the coverage effect.

10. The method for manufacturing the bottom terminal of the LED die structure as recited in claim 9 wherein the wafer is divided into dies by use of the cutting or breakup process.
